(19) United States
(12) Patent Application Publication
(10) Pub. No.: US 2016/0365063 A1
(43) Pub. Date: Dec. 15, 2016

(54) LEVEL SHIFTER AND SOURCE DRIVER INTEGRATED CIRCUIT

(71) Applicant: SILICON WORKS CO., LTD., Daejeon (KR)

(72) Inventors: JungIl SEO, Daejeon (KR); YongIk JUNG, Bucheon-si (KR); JungBae YUN, Seoul (KR)

(21) Appl. No.: 15/176,587

(22) Filed: Jun. 8, 2016

(30) Foreign Application Priority Data
Jun. 12, 2015 (KR) 10-2015-0083137

(51) Int. Cl. G09G 5/00; H03K 19/0185

(52) U.S. Cl. CPC G09G 5/003; H03K 19/018507; G09G 2310/0289; G09G 2310/027; G09G 2310/0291; G09G 2300/08; G09G 2310/08

(57) ABSTRACT

The present embodiments relate to an advanced level shifter having a circuit structure which enables miniaturization and high performance, a source driver integrated circuit and a gate driver integrated circuit, and a display device which include the same.

### CROSS REFERENCE TO RELATED APPLICATION

This application claims priority from Korean Patent Application No. 10-2015-0083137, filed on Jun. 12, 2015, which is hereby incorporated by reference for all purposes as if fully set forth herein.

### BACKGROUND

1. Field of the Invention

The present embodiments relate to a level shifter, a source driver integrated circuit, and a gate driver integrated circuit.

2. Description of the Prior Art

An electric device such as a display device may include a level shifter for changing voltage levels of various voltage signals to required voltage levels.

The level shifter is configured to a circuit including a plurality of transistors in order to output an output signal of a high voltage level which is shifted by receiving an input signal of a low voltage level. Further, when the conventional level shifter intends to change a voltage level of the input signal to a voltage level of a desired level, the conventional level shifter does not rapidly change the voltage level to a desired voltage level.

Further, in order to rapidly change the voltage level to the desired voltage, a large-size transistor is needed. Therefore, in the conventional level shifter, there are problems in that a chip size increases and an output signal, in which a rising or falling characteristic is not good, is output.

### SUMMARY

According to the present embodiments, provided are an advanced level shifter which enables a rapid voltage level conversion, and a source driver integrated circuit and a gate driver integrated circuit which include the same.

According to the present embodiments, provided are an advanced level shifter which has a circuit structure allowing miniaturization and high performance, and a source driver integrated circuit and a gate driver integrated circuit which include the same.

According to the present embodiments, provided are a level shifter which implements a transistor receiving an input signal as a low voltage transistor, and a source driver integrated circuit and a gate driver integrated circuit which include the same.

According to the present embodiments, provided are a level shifter which reduces a deviation between a rising time and a falling time of an output signal and shortens the rising time, and a source driver integrated circuit and a gate driver integrated circuit which include the same.

In accordance with an aspect of the present invention, there is provided a level shifter. The level shifter includes: a low voltage input circuit including first and second N-channel transistors which receive an input signal of a low voltage level and an inversion input signal obtained by inverting the input signal; a high voltage output circuit for receiving a driving voltage and outputting, to first and second output ports, an output signal of a high voltage level corresponding to a voltage level of the driving voltage and an inversion output signal obtained by inverting the output signal; and a voltage drop circuit configured to be electrically connected between drain nodes of the first and second N-channel transistors of the low voltage input circuit and the first and second output ports of the high voltage output circuit, and allow voltage levels of the drain nodes of the first and second N-channel transistors to be lower than voltage levels of the first and second output ports.

In accordance with another aspect of the present invention, there is provided a level shifter. The level shifter includes: an input transistor for receiving an input signal of a predetermined voltage level; an output transistor for outputting an output signal of a voltage level higher than a voltage level of the input signal; and a voltage drop transistor which is controlled by a bias voltage and is electrically connected between a gate node of the output transistor and a drain node of the input transistor.

In accordance with another aspect of the present invention, there is provided a source driver integrated circuit. The source driver integrated circuit includes: a latch circuit for storing a digital image signal; a level shifter for shifting a voltage level of the digital image signal; a digital analog converter for converting a digital image signal having a shifted voltage level, into an analog image signal; and an output buffer for outputting the analog image signal.

In the source driver integrated circuit, the level shifter may include: a low voltage input circuit including first and second N-channel transistors which receive an input signal corresponding to a digital image signal and an inversion input signal obtained by inverting the input signal; a high voltage output circuit for receiving a driving voltage and outputting, to first and second output ports, an output signal of a high voltage level corresponding to a voltage level of the driving voltage and an inversion output signal obtained by inverting the output signal; and a voltage drop circuit configured to be electrically connected between drain nodes of the first and second N-channel transistors of the low voltage input circuit and the first and second output ports of the high voltage output circuit, and allow voltage levels of the drain nodes of the first and second N-channel transistors to be lower than the output signal or the inversion output signal.

In accordance with another aspect of the present invention, there is provided a display device. The display device includes: a display panel in which a plurality of data lines and a plurality of gate lines are arranged; and a data driving unit for driving the plurality of data lines; and a gate driving unit for driving the plurality of gate lines.

In the display device, the data driving unit may include at least one source driver integrated circuit including a level shifter for shifting a voltage level of the input digital image signal.

A level shifter included in each source driver integrated circuit may include: a low voltage input circuit including first and second N-channel transistors which receive an input signal corresponding to a digital image signal and an inversion input signal obtained by inverting the input signal; a high voltage output circuit for receiving a driving voltage and outputting, to first and second output ports, an output signal of a high voltage level corresponding to a voltage level of the driving voltage and an inversion output signal obtained by inverting the output signal; and a voltage drop circuit configured to be electrically connected between drain nodes of the first and second N-channel transistors of the low voltage input circuit and the first and second output ports of the high voltage output circuit, and allow voltage levels of the drain nodes of the first and second N-channel transistors to be lower than the output signal or the inversion output signal.

In accordance with another aspect of the present invention, there is provided a gate driver integrated circuit. The gate driver integrated circuit includes: a shift resistor for generating and outputting a logic signal for determining turning on/off of the gate lines on the basis of a gate control signal; a level shifter for shifting and outputting a voltage level of a logic signal output from the shift resistor; and an output buffer for outputting a signal output from the level shifter to the gate lines as a scan signal.

In the gate driver integrated circuit, the level shifter may include: a low voltage input circuit including first and second N-channel transistors which receive an input signal corresponding to the logic signal and an inversion input signal obtained by inverting the input signal; a high voltage output circuit for receiving a driving voltage and outputting, to first and second output ports, an output signal of a high voltage level corresponding to a voltage level of the driving voltage and an inversion output signal obtained by inverting the output signal; and a voltage drop circuit configured to be electrically connected between drain nodes of the first and second N-channel transistors of the low voltage input circuit and the first and second output ports of the high voltage output circuit, and allow voltage levels of the drain nodes of the first and second N-channel transistors to be lower than the output signal or the inversion output signal.

According to the present embodiments as described above, an advanced level shifter which enables a rapid voltage level conversion, and a source driver integrated circuit and a gate driver integrated circuit which include the same can be provided.

Further, according to the present embodiments, an advanced level shifter which has a circuit structure allowing miniaturization and high performance, and a source driver integrated circuit and a gate driver integrated circuit which include the same can be provided.

Further, according to the present embodiments, a level shifter which implements a transistor receiving an input signal as a low voltage transistor, and a source driver integrated circuit and a gate driver integrated circuit which include the same can be provided.

Further, according to the present embodiments, a level shifter which reduces a deviation between a rising time and a falling time of an output signal and shortens the rising time, and a source driver integrated circuit and a gate driver integrated circuit which include the same can be provided.

### BRIEF DESCRIPTION OF THE DRAWINGS

The above and other objects, features and advantages of the present invention will be more apparent from the following detailed description taken in conjunction with the accompanying drawings, in which:

FIG. 1 is a circuit diagram illustrating a basic level shifter according to the present embodiments;

FIG. 2 illustrates a waveform of an output signal of the basic level shifter according to the present embodiments;

FIGS. 3 to 5 are circuit diagrams illustrating an advanced level shifter according to the present embodiments;

FIGS. 6 and 7 are circuit diagrams illustrating an operation of the advanced level shifter according to the present embodiments;

FIG. 8 illustrates a waveform of an output signal of the advanced level shifter according to the present embodiments;

FIG. 9 is a graph illustrating comparison of a performance and a size between the basic level shifter and the advanced level shifter according to the present embodiments;

FIG. 10 is a system configuration diagram illustrating a display device according to the present embodiments;

FIG. 11 is a block diagram of a source driver integrated circuit in the display device according to the present embodiments; and

FIG. 12 is a block diagram of a gate driver integrated circuit in the display device according to the present embodiments.

### DETAILED DESCRIPTION

Hereinafter, some embodiments of the present invention will be described in detail with reference to the accompanying illustrative drawings. In designating elements of the drawings by reference numerals, the same elements will be designated by the same reference numerals although they are shown in different drawings. Further, in the following description of the present invention, a detailed description of known functions and configurations incorporated herein will be omitted when it may make the subject matter of the present invention rather unclear.

In addition, terms, such as first, second, A, B, (a), (b) or the like may be used herein when describing components of the present invention. Each of these terminologies is not used to define an essence, order or sequence of a corresponding component but used merely to distinguish the corresponding component from other component(s). In the case that it is described that a certain structural element “is connected to”, “is coupled to”, or “is in contact with” another structural element, it should be interpreted that another structural element may “be connected to”, “be coupled to”, or “be in contact with” the structural elements as well as that the certain structural element is directly connected to or is in direct contact with another structural element.

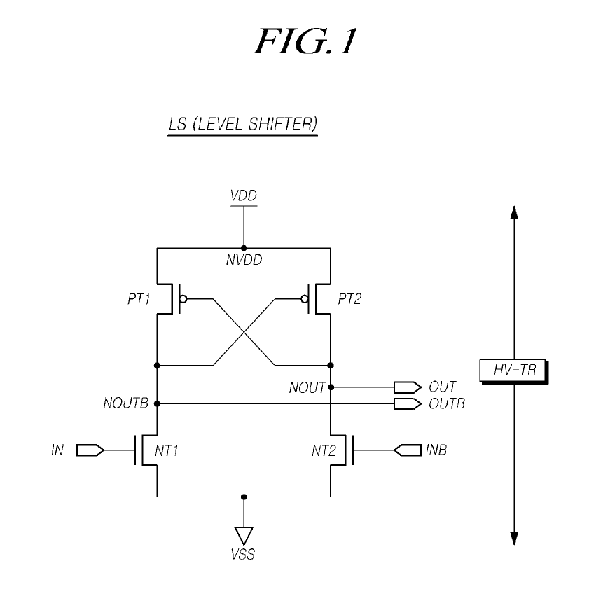

FIG. 1 is a circuit diagram illustrating a basic Level Shifter (LS) according to the present embodiments.

Referring to FIG. 1, a basic Level Shifter (LS) according to the embodiments is configured by a low voltage input circuit and a high voltage output circuit.

Referring to FIG. 1, the low voltage input circuit may include a first N-channel transistor (NT1) which receives an input signal (IN) of a low voltage level (e.g., 0V˜1.8V), and a second N-channel transistor (NT2) which receives an inversion input signal (INB) obtained by inverting the input signal.

Referring to FIG. 1, a high voltage output circuit may receive a driving voltage (VDD) and output, to first and second output ports (NOUT and NOUTB), an output signal (OUT) of a high voltage level (e.g., 0V˜18V) corresponding to a voltage level (e.g., 18V) of the driving voltage (VDD) and an inversion output signal (OUTB) obtained by inverting the output signal.

The high voltage output circuit may include a first high voltage output transistor (PT1), which has a source node electrically connected to a driving voltage supply node (NVDD) to which the driving voltage (VDD) of the high voltage level (e.g., 18V) is supplied, a drain node electrically connected to a second output port (NOUTB), and a gate node electrically connected to a first output port (NOUT), and a second high voltage output transistor (PT2), which has a source node electrically connected to a driving voltage supply node (NVDD) to which the driving voltage (VDD) of the high voltage level (e.g., 18V) is supplied, a drain node electrically connected to the first output port (NOUT), and a gate node electrically connected to the second output port (NOUTB).

Herein, the first high voltage output transistor (PT1) and the second high voltage output transistor (PT2) may be, for example, P-channel transistors.

All transistors (NT1, NT2, PT1, and PT2) configuring the basic level shifter (LS) as shown in FIG. 1 are “high voltage transistors (HV-TR)” in which a High Voltage (HV) higher than an upper limit reference voltage (e.g., about 4V) of a pre-defined low voltage level is applied to the drain node (or source node).

In the basic level shifter (LS) as shown in FIG. 1, since voltage levels (e.g., 1.8V) of the input signals (IN) which are applied to the first and second N-channel transistors (NT1 and NT2) corresponding to the high voltage transistor (HV-TR) are much lower than turn-on levels (e.g., 18V) of the first and second N-channel transistors (NT1 and NT2), the first and second N-channel transistors (NT1 and NT2) may not be “fully turned on” and may be “slightly turned on”.

Therefore, the first and second N-channel transistors (NT1 and NT2) which are “slightly turned on” make a current to flow smaller in comparison with a case in which the first and second N-channel transistors (NT1 and NT2) which are “fully turned on”.

When a current is allowed to flow at a desired level, channel widths of the first and second N-channel transistors (NT1 and NT2) should be designed to be large. This enables a whole size of the level shifter (LS) as well as sizes of the first and second N-channel transistors (NT1 and NT2) to be large.

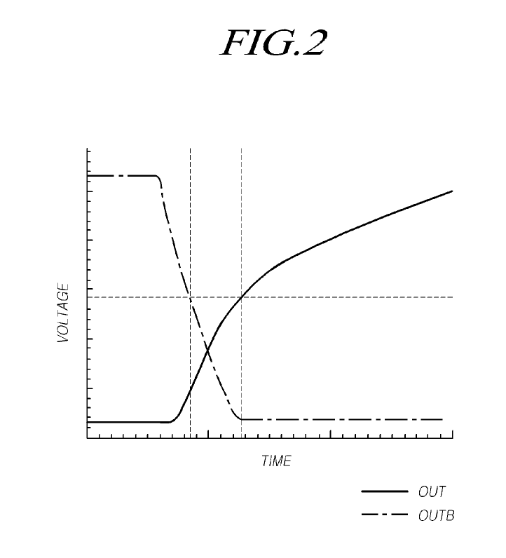

Further, when designing to make the level shifter (LS) operate in a change condition such as a process/voltage/temperature, a basic level shifter (LS) including the first and second N-channel transistors (NT1 and NT2) which are not “fully turned on”, are “slightly turned on”, and correspond to the high voltage transistor (HV-TR), in a typical condition, as shown in FIG. 2, a rising time and a falling time of the output signal (OUT) or the inversion output signal (OUTB) may lengthen and an overlapped interval may lengthen. Further, a deviation between the rising time and the falling time of the output signal may largely occur.

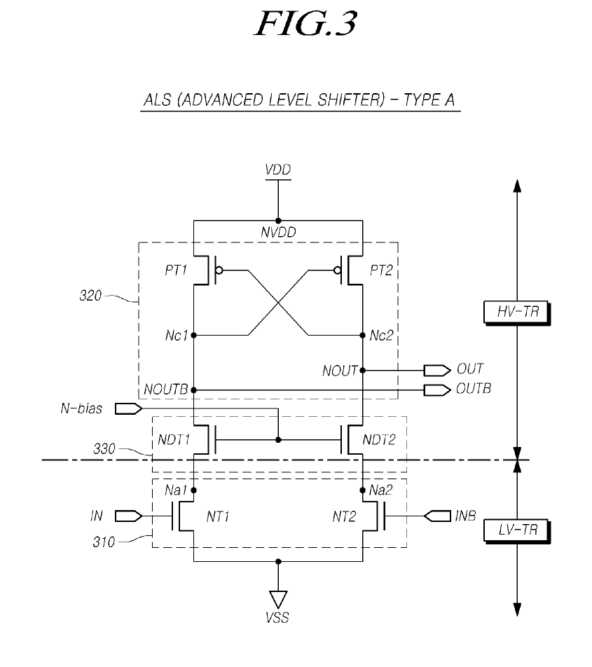

An “Advanced Level Shifter (ALS)” which can resolve demerits of the basic level shifter (LS) will be described with reference to FIGS. 3 to 9.

FIGS. 3 to 5 are circuit diagrams illustrating structures of three types (type A, type B, and type C) of the advanced level shifter (ALS) according to the present embodiments.

Referring to FIGS. 3 to 5, regardless of a type, the advanced level shifter (ALS) according to the present embodiments is configured by a low voltage input circuit 310, a high voltage output circuit 320, a voltage drop circuit 330, and the like.

First, FIG. 3 illustrates an advanced level shifter (ALS) having a type A structure which is the most simple structure.

The low voltage input circuit 310 may include a first N-channel transistors (NT1) which receives an input signal (IN) of a low voltage level and a second N-channel transistor (NT2) which receives an inversion input signal (INB) obtained by inverting the input signal.

In the low voltage input circuit 310, the first N-channel transistor (NT1) includes a source node to which a base voltage (VSS) such as a ground voltage is applied, a gate node to which an input signal (IN) is applied, and a drain node (Na1) electrically connected to a second output port (NOUTB).

In the low voltage input circuit 310, the second N-channel transistor (NT2) includes a source node to which a base voltage (VS S) is applied, a gate node to which an inversion input signal (INB) is applied, and a drain node (Na2) electrically connected to a first output port (NOUT).

The high voltage output circuit 320 may receive a driving voltage (VDD) and output, to first and second output ports (NOUT and NOUTB), an output signal (OUT) of a high voltage level corresponding to a voltage level (e.g., 18V) of the driving voltage (VDD) and an inversion output signal (OUTB) obtained by inverting the output signal.

The high voltage output circuit 320 may include a first high voltage output transistor (PT1) and a second high voltage output transistor (PT2).

The first high voltage output transistor (PT1) has a source node electrically connected to a driving voltage supply node (NVDD) to which the driving voltage (VDD) of the high voltage level (e.g., 18V) is supplied, a drain node electrically connected to a second output port (NOUTB), and a gate node electrically connected to a first output port (NOUT).

The second high voltage output transistor (PT2) has a source node electrically connected to a driving voltage supply node (NVDD) to which the driving voltage (VDD) of the high voltage level (e.g., 18V) is supplied, a drain node electrically connected to the first output port (NOUT), and a gate node electrically connected to the second output port (NOUTB).

As shown in FIG. 3, the first high voltage output transistor (PT1) and the second high voltage output transistor (PT2) which are included in the high voltage output circuit 320 may be, for example, P-channel transistors.

The voltage drop circuit 330 is electrically connected between the drain nodes (Na1 and Na2) of the first and second N-channel transistors (NT1 and NT2) in the low voltage input circuit 310 and the first and second output ports (NOUT and NOUTB) in the high voltage output circuit 320, and may lower voltage levels (e.g., less than or equal to about 4V) of the drain nodes (Na1 and Na2) of the first and second N-channel transistors (NT1 and NT2) than voltage levels (e.g., about 18V) of the first and second output ports (NOUT and NOUTB).

The voltage drop circuit 330 may include, for example, a first voltage drop transistor (NDT1) and a second voltage drop transistor (NDT2).

As shown in FIG. 3, the first voltage drop transistor (NDT1) and the second voltage drop transistor (NDT2) included in the voltage drop circuit 330 may be, for example, N-channel transistors.

The first voltage drop transistor (NDT1) and the second voltage drop transistor (NDT2) may receive a bias voltage (N-bias) to the gate node in common, and may be always turned on by the bias voltage (N-bias) applied to the gate node.

The first voltage drop transistor (NDT1), to which the bias voltage (N-bias) is applied to the gate node, may be electrically connected between the drain node (Na1) of the first N-channel transistor (NT1) and the second output port (NOUTB).

The second voltage drop transistor (NDT2), to which the bias voltage (N-bias) is applied to the gate node, may be electrically connected between the drain node (Na2) of the second N-channel transistor (NT2) and the first output port (NOUT).

Meanwhile, referring to FIG. 3, the first high voltage output transistor (PT1) and the second high voltage output transistor (PT2) included in the high voltage output circuit 320 and the first voltage drop transistor (NDT1) and the second voltage drop transistor (NDT2) included in the voltage drop circuit 330 correspond to a “high-voltage transistor (HV-TR)” in which a High Voltage (HV), which is higher than an upper limit reference voltage (e.g., about 4V) of a pre-defined low voltage level, is applied to the drain node.

As described above, the first voltage drop transistor (NDT1) and the second voltage drop transistor (NDT2) are designed as the high voltage transistors, and voltages applied to a drain node (or source node) of the first voltage drop transistor (NDT1) connected to the second output port (NOUTB) and a drain node (or source node) of the second voltage drop transistor (NDT2) connected to the first output port (NOUT) are designed to be higher than voltages applied to a drain node (or source node, Nb1) of a first margin control transistor (MT1) and a drain node (or source node, Nb2) of a second margin control transistor (MT2) so that the low voltage transistors (MT1, MT2, NT1, and NT2) in the level shifter may be protected.

In comparison, the first and second N-channel transistors (NT1 and NT2) included in the low voltage input circuit 310 correspond to “low-voltage transistor (LV-TR)” in which a Low Voltage (LV), which is less than or equal to an upper limit reference voltage (e.g., about 4V) of the pre-defined low voltage level, is applied to the drain node (or source node).

Accordingly, due to a voltage drop according to the voltage drop circuit 330, voltages of the drain nodes (Na1 and Na2) of the first and second N-channel transistors (NT1 and NT2) included in the low voltage input circuit 310 may be less than or equal to the upper limit reference voltage (e.g., about 4V) of the low voltage level.

That is, according to a voltage drop between the drain nodes and the source nodes in the first and second voltage drop transistors (NDT1 and NDT2) included in the voltage drop circuit 330, voltages of the drain nodes (Na1 and Na2) of the first and second N-channel transistors (NT1 and NT2) included in the low voltage input circuit 310 are less than or equal to the upper limit reference voltage (e.g., about 4V) of the low voltage level, and the first and second N-channel transistors (NT1 and NT2) may operate as a “low voltage transistor (LV-TR)”.

As described above, since the first and second N-channel transistors (NT1 and NT2) operate as the “low voltage transistor (LV-TR)” by the first and second voltage drop transistors (NDT1 and NDT2) included in the voltage drop circuit 330, channel widths of the first and second N-channel transistors (NT1 and NT2) may be designed to be small.

A size reduction of the first and second N-channel transistors (NT1 and NT2) is larger than a size increase by an additional configuration of the voltage drop circuit 330 in FIG. 3. Therefore, a whole size of the advanced level shifter having a type A structure (ALS-type A) may be considerably reduced.

However, due to a reason such as a process error, a voltage drop by the first and second voltage drop transistors (NDT1 and NDT2) included in the voltage drop circuit 330 may not be implemented at a desired level. Therefore, the voltages of the drain nodes (Na1 and Na2) of the first and second N-channel transistors (NT1 and NT2) included in the low voltage input circuit 310 may increase in comparison with the upper limit reference voltage (e.g., about 4V) of the low voltage level.

The first and second N-channel transistors (NT1 and NT2) included in the low voltage input circuit 310 may not be “fully turned on” and may be “slightly turned on”.

Therefore, the advanced level shifter (ALS) according to the embodiments may further include an additional circuit configuration for voltage margin securement in order to prevent the voltages of the drain nodes (Na1 and Na2) of first and second N-channel transistors (NT1 and NT2) included in the low voltage input circuit 310 from lowering to the desired level due to a reason such as a process error.

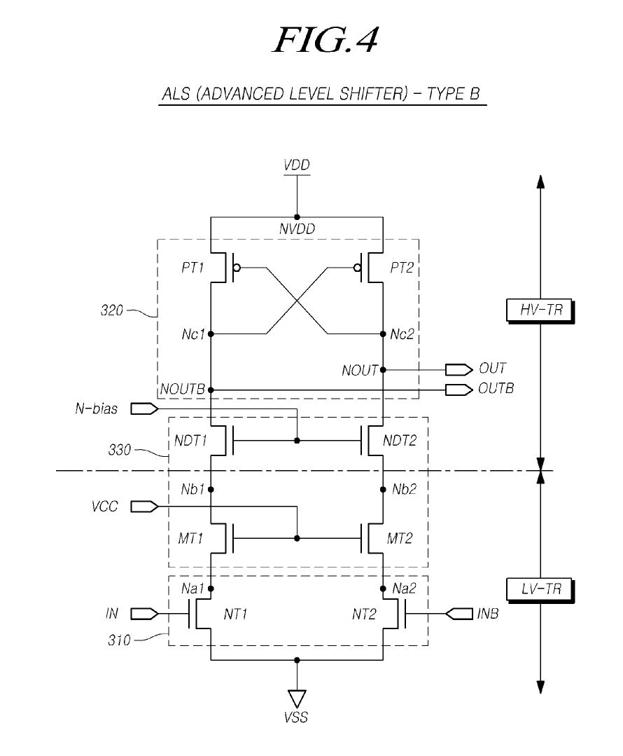

As described above, a type of the advanced level shifter (ALS), to which the circuit configuration for the voltage margin securement is added, is referred to as a type B. This will be described with reference to FIG. 4.

Referring to FIG. 4, in an advanced level shifter which has a type B structure (ALS-Type B), a voltage drop circuit 330 may further include a first margin control transistor (MT1) and a second margin control transistor (MT2) so as to allow voltages of drain nodes (Na1 and Na2) of first and second N-channel transistors (NT1 and NT2) included in a low voltage input circuit 310 to be lowered to a desired level under any circumstance.

The advanced level shifter which has the type B structure (ALS-Type B) as shown in FIG. 4 is identical to the advanced level shifter which has the type A (ALS-Type A) with regard to the remaining circuit elements except for that a voltage drop circuit 330 further includes the first margin control transistor (MT1) and the second margin control transistor (MT2).

Therefore, in describing the advanced level shifter which has the type B structure (ALS-Type B), the description will mainly focus on a part that differs with the advanced level shifter which has the type A structure (ALS-Type A), i.e., a circuit configuration (the first margin control transistor (MT1) and the second margin control transistor (MT2)) for the voltage margin securement.

The first margin control transistor (MT1) and the second margin control transistor (MT2) corresponding to the circuit configuration for the voltage margin securement, may be, for example, N-channel transistors.

Referring to FIG. 4, the first margin control transistor (MT1) may be electrically connected between a first voltage drop transistor (NDT1) and a drain node (Na1) of the first N-channel transistor (NT1).

The second margin control transistor (MT2) may be electrically connected between a second voltage drop transistor (NDT2) and a drain node (Na2) of the second N-channel transistor (NT2).

The first margin control transistor (MT1) and the second margin control transistor (MT2) may receive a predetermined gate voltage (VCC) by a gate node in common.

Further, the first margin control transistor (MT1) and the second margin control transistor (MT2) may be always turned on.

Referring to FIG. 4, although the voltages of the drain nodes (Nb1 and Nb2) of the first and second voltage drop transistors (NDT1 and NDT2) increase in comparison with an upper limit reference voltage (e.g., about 4V) of a low voltage level, an additional voltage drop by the first margin control transistor (MT1) and the second margin control transistor (MT2) occurs so that the drain nodes (Na1 and Na2) of the first and second N-channel transistors (NT1 and NT2) may be lowered to the desired level (low voltage level).

Therefore, the first and second N-channel transistors (NT1 and NT2) may operate as “low voltage transistors (LV-TR)” so as to be “fully turned on”.

Therefore, a Rising Time (RT) and a Falling Time (FT) of an output signal (OUT) or an inversion output signal (OUTB) may be further shortened, and a deviation (ART-FT) between the RT and the FT may be greatly shortened.

As described above, the first and second N-channel transistors (NT1 and NT2) may operate as a “low voltage transistor (LV-TR)” so as to be “fully turned on”. Further, first and second N-channel transistors (NT1 and NT2) may design a channel width thereof to be small.

A size reduction of the first and second N-channel transistors (NT1 and NT2) is larger than a size increase by an additional configuration of the voltage drop circuit 330 in FIG. 4. Therefore, a whole size of the advanced level shifter having the type B structure (ALS-type B) may be considerably reduced.

Meanwhile, referring to FIG. 4, a first high voltage output transistor (PT1) and a second high voltage output transistor (PT2) included in the high voltage output circuit 320 and the first voltage drop transistor (NDT1) and the second voltage drop transistor (NDT2) included in the voltage drop circuit 330 correspond to “high-voltage transistors (HV-TR)” in which a High Voltage (HV), which is higher than an upper limit reference voltage (e.g., about 4V) of a low voltage level, is applied to the drain node.

In comparison, the first and second N-channel transistors (NT1 and NT2) included in the low voltage input circuit 310 correspond to “low-voltage transistors (LV-TR)” in which a Low Voltage (LV), which is less than an upper limit reference voltage (e.g., about 4V) of the low voltage level, is applied to the drain node.

Further, the first margin control transistor (MT1) and the second margin control transistor (MT2) included in the voltage drop circuit 300 may be “low voltage transistor (LV-RT)” in which an upper limit reference voltage (e.g., about 4V) of a low voltage level is applied to the drain node.

Meanwhile, a voltage higher than the upper limit reference voltage (e.g., about 4V) of the low voltage level is not defined as a High Voltage (HV) level, and may be further subdivided into a Middle Voltage (MV) level and a High Voltage (HV) level.

In this event, the first and second margin control transistors (MT1 and MT2) may be “middle voltage transistors (MV-TR)” in which a middle voltage, which is higher than the upper limit reference voltage (e.g., about 4V) of the low voltage level and less than or equal to an upper limit reference voltage (e.g., about 8˜10V) of the middle voltage level, is applied to the drain node.

Meanwhile, in the advanced level shifter having the type A (ALS-Type A) as shown in FIG. 3 or the advanced level shifter having the type B (ALS-Type B) as shown in FIG. 4, in order to control a current flowing into the first high voltage output transistor (PT1) and the second high voltage output transistor (PT2) included in the high voltage output circuit 320 to be small, a circuit for controlling a current may be additionally configured to the high voltage circuit 320.

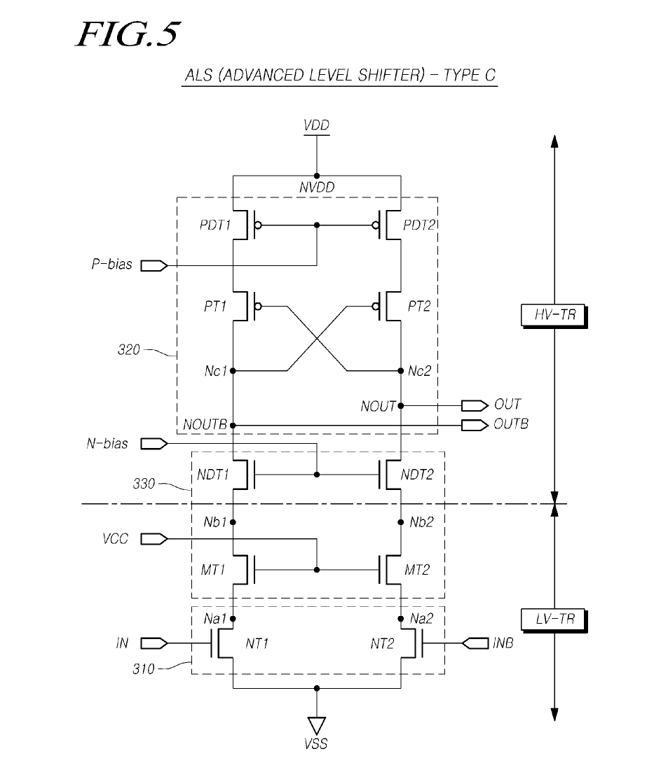

Hereinafter, a case in which the circuit for controlling a current may be additionally configured to the high voltage circuit 320 in the advanced level shifter having the type B (ALS-Type B) as shown in FIG. 4 will be described with reference to FIG. 5.

An advanced level shifter as shown in FIG. 5 is referred to as an advanced level shifter having a type C (ALS-type C).

Referring to FIG. 5, in the advanced level shifter having the type C (ALS-type C), the high voltage output circuit 320 may further include a first current control transistor (PDT1) and a second current control transistor (PDT2) as a current control circuit configuration.

Referring to FIG. 5, the first current control transistor (PDT1) may be controlled by a bias voltage (P-bias) and be connected between source nodes of a driving voltage supply node (NVDD) and a first high voltage output transistor (PT1).

The second current control transistor (PDT2) may be controlled by the bias voltage (P-bias) and be connected between source nodes of the driving voltage supply node (NVDD) and a second high voltage output transistor (PT2).

A voltage drop occurs by the first current control transistor (PDT1) and the second current control transistor (PDT2) so that voltages of drain nodes (Nc1 and Nc2) of the first voltage output transistor (PT1) and the second high voltage output transistor (PT2) may lower in comparison with the driving voltage (VDD).

Therefore, a voltage of an output signal (OUT) or an inversion output signal (OUTB) may be a voltage which, although being a high voltage level, is not the driving voltage (VDD) but a voltage a little lower than the voltage.

Further, the first current control transistor (PDT1) and the second current control transistor (PDT2) may control a current flowing to the first voltage output transistor (PT1) and the second high voltage output transistor (VT2) to be small.

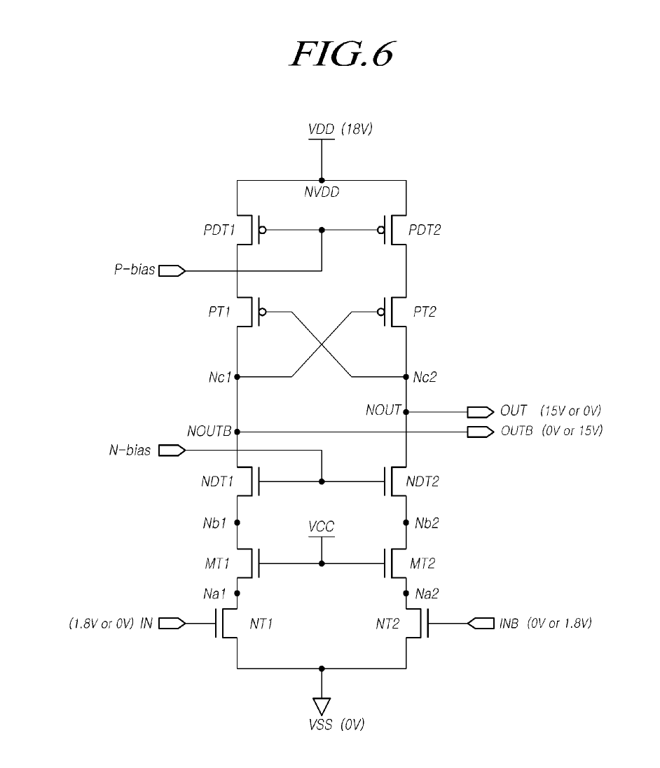

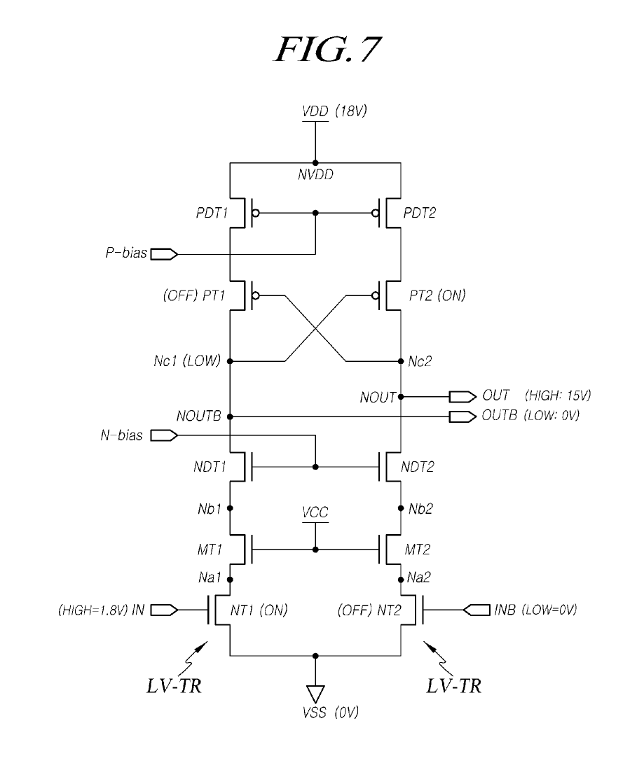

FIGS. 6 and 7 are circuit diagrams illustrating an operation of the Advanced Level Shifter (ALS) according to the present embodiments.

As an example, an operation of the advanced level shifter having the type C (ALS-type C) will be described.

Before describing the operation of the Advanced Level Shifter (ALS) according to the present embodiments, a voltage of a main node will be illustrated in FIG. 6.

Referring to FIG. 6, first and second N-channel transistors (NT1 and NT2) belonging to a low voltage input circuit 310 receive an input signal (IN) or an inversion input signal (INB) which is, for example, 1.8V.

Herein, the input signal (IN) or the inversion input signal (INB) may be a logic signal, and may be output as a high level of 1.8V or be provided as a low level (LOW) of 0V.

The advanced level shifter (ALS) according to the present embodiments receives an input signal (IN) of the low voltage level of 1.8 V and outputs the output signal (OUT) of the high voltage level which is, for example, about 15V. Herein, the output signal (OUT) corresponds to a signal having a waveform corresponding to the input signal (IN). Further, the inversion output signal (OUTB) corresponds to a signal having a waveform corresponding to the inversion input signal (INB).

Herein, the output signal (OUT) or the inversion output signal (OUTB) may be a logic signal, and may be output as a high logic level of 15V or be output as a low logic level (LOW) of 0V.

Referring to FIG. 7, when an input signal (IN) corresponding to a logic signal of a high logic level (HIGH) is applied to a gate node of a first N-channel transistor (NT1), i.e., when an input signal (IN) having a voltage (1.8V) of a low voltage level is applied to the gate node of the first N-channel transistor (NT1), the first N-channel transistor (NT1) is turned on.

Therefore, a drain node of the first N-channel transistor (NT1) becomes a voltage state of a low logic level (LOW) due to a base voltage (VSS).

According to a state in which a first margin control transistor (MT1) and a first voltage drop transistor (NDT1) are turned on, a second output port (NOUTB) also becomes a voltage state of the low logic level (LOW). Therefore, the inversion output signal (OUTB) of 0V corresponding to the low logic level (LOW) is output to the second output port (NOUTB). Since the inversion output signal (OUTB) may be output as 15V, the inversion output signal (OUTB) corresponds to a high voltage level.

Therefore, since a gate node of a second high voltage output transistor (PT2) electrically connected to the second output port (NOUTB) also becomes a voltage state of the low logic level (LOW), the second high voltage output transistor (PT2) corresponding to a P-channel transistor is turned on.

A voltage (about 15V) which is voltage-dropped with reference to the driving voltage (VDD) is applied to the first output port (NOUT) because a second current control transistor (PDT2) is turned on. That is, the first output port (NOUT) is to be in a voltage state of the high logic level (HIGH) of about 15V.

Therefore, an output signal (OUT) of a high voltage level of 15V corresponding to the high logic level (HIGH) is output to the first output port (NOUT). Since the first output port (NOUT) is in a voltage state of the high logic level (HIGH), a first high voltage output transistor (PT1) corresponding to a P-channel transistor is in an off-state.

As described above, the first high voltage output transistor (PT1) receives a driving voltage (VDD) and outputs an inversion output signal (OUTB) to the second output port (NOUTB), and the second high voltage output transistor (PT2) receives the driving voltage (VDD) and outputs an output signal (OUT) to the first output port (NOUT).

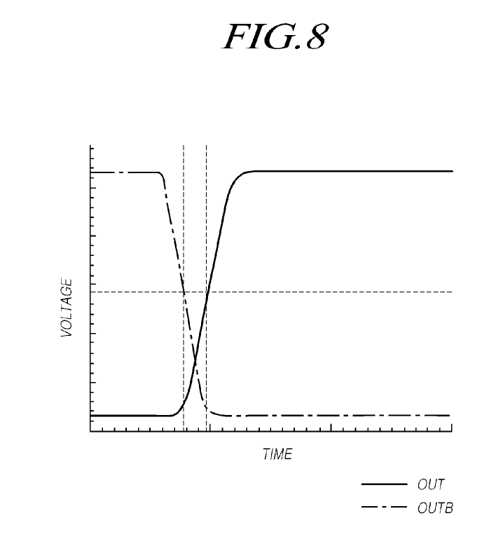

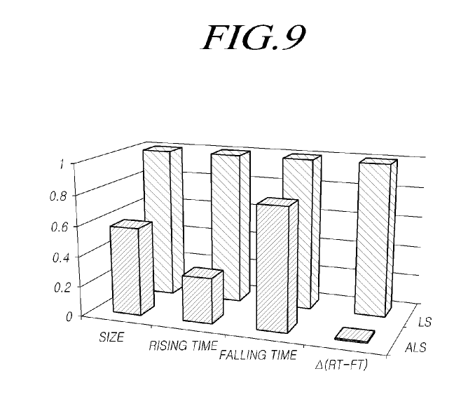

FIG. 8 illustrates a waveform of an output signal of the advanced level shifter according to the present embodiments, and FIG. 9 is a graph illustrating a comparison of a performance and a size between the basic Level Shifter (LS) and the advanced level shifter (ALS) according to the present embodiments.

Referring to FIG. 8, an advanced level shifter (ALS) according to the embodiments may identify that a rising time and a falling time are shortened in comparison with the output signal (FIG. 2) of the basic level shifter (LS).

This will be identified through FIG. 9, and referring to FIG. 9, when a rising time of a basic level shifter (LS) is 1.00, a rising time of the advanced level shifter (ALS) becomes 0.30 so that the rising time may be shortened by about 70%.

Further, referring to FIG. 9, when a falling time of the basic level shifter (LS) is 1.00, a falling time of the advanced level shifter (ALS) becomes 0.80 so that the falling time may be shortened by about 20%.

With respect to a reduction of the rising time and falling time as well as a deviation (A (RT-FT)) between the rising time and falling time, when a deviation of the basic level shifter (LS) is 1.00, the deviation of the advanced level shifter (ALS) becomes 0.01, thereby reducing the deviation by about 90%.

The reduction of the rising time and falling time relates to the fact that the first and second N-channel transistors (NT1 and NT2) operate as low voltage transistors (LV-TR) to be “fully turned on”.

As described above, when the first and second N-channel transistors (NT1 and NT2) are “fully turned on”, since the first and second N-channel transistors make a lot of current flow in comparison with being “slightly turned on”, the first and second N-channel transistors make a desired performance and may design a channel width of the first and second N-channel transistors (NT 1 and NT 2) to be small.

Therefore, in a case of the advanced level shifter (ALS), a size thereof can be largely reduced in comparison with a size of the basic level shifter (LS).

Referring to FIG. 9, when the size of the basic level shifter (LS) is 1.00, the size of the advanced level shifter (ALS) becomes 0.58 so that the size thereof is reduced by about 42%.

Hereinafter, an example in which the level shifter (ALS) according to the present embodiments as described above is utilized as a circuit for shifting voltage levels of various voltages used in a display device.

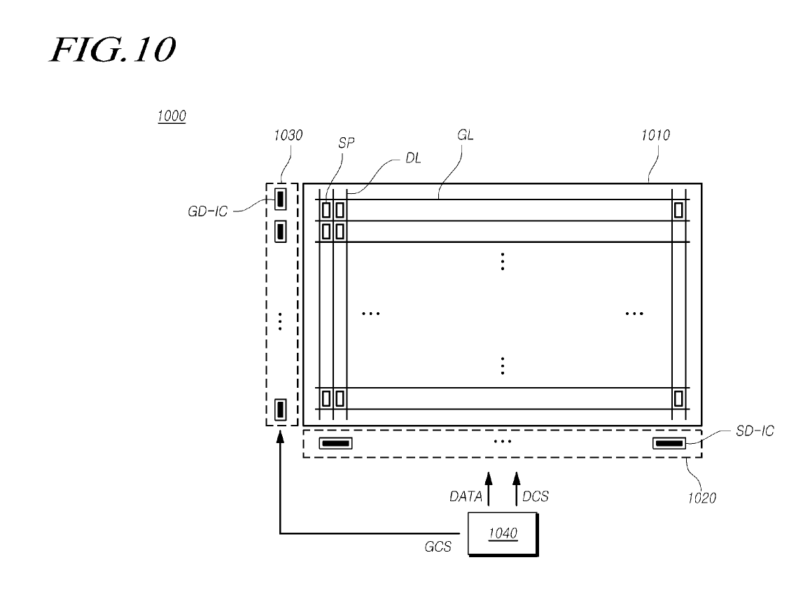

FIG. 10 is a system configuration diagram illustrating a display device 1000 according to the present embodiments.

Referring to FIG. 10, the display device 1000 according to the embodiments may include a display panel 1010 in which a plurality of data lines (DL) and a plurality of gate lines (GL) are arranged and a plurality of subpixels (SP) are arranged, a data driving unit 1020 for driving a plurality of data lines (DL), a gate driving unit 1030 for driving a plurality of gate lines (GL), and a timing controller 1040 for controlling the data driving unit 1020 and the gate driving unit 1030, and the like.

The data driving unit 1020 converts a digital image signal (image data, DATA) input from the timing controller 1040, into a data voltage corresponding to an analog image signal and supplies the converted voltage to a plurality of data lines, thereby driving the plurality of data lines.

The gate driving unit 1030 sequentially supplies a scan signal to the plurality of gate lines, thereby sequentially driving the plurality of gate lines (GL).

The timing controller 1040 supplies various control signals (DCS and GCS) to the data driving unit 1020 and the gate driving unit 1030 and then controls the data driving unit 1020 and the gate driving unit 1030.

The timing controller 1040 starts scanning according to timing implemented in each frame, and changes image data input from the outside to be suitable for a data signal type used in the data driving unit 1020, outputs a digital image signal (DATA) corresponding to the changed image data, and controls data driving at proper time according to the scanning.

The gate driving unit 1030 sequentially supplies a scanning signal of an on voltage or an off voltage to the plurality of gate lines under a control of the timing controller 1040 to sequentially drive the plurality of gate lines.

The gate driving unit 1030 may be located at a side of the display panel 1010 as shown in FIG. 10 according to the driving scheme, and may be located at both sides thereof in some cases.

The gate driving unit 1020 may include two or more Gate Driver Integrated Circuits (GD-IC).

The Gate Driver Integrated Circuits (GD-IC) may include a shift register, a level shifter, an output buffer, and the like.

The two or more Gate Driver Integrated Circuits (GD-IC) may be connected to a bonding pad of the display panel 1010 in a Tape Automated Bonding (TAB) scheme or Chip On Glass (COG) scheme or may be directly arranged in the display panel 1010 by being implemented in a Gate In Panel (GIP) type. In some cases, the two or more Gate Driver Integrated Circuits (GD-IC) may be integrated and arranged into the display panel 1010.

When a specific gate line is opened, the data driving unit 1020 converts image data received from the timing controller 1040, into data voltage in an analog type and then supplies the converted voltage to the data lines, thereby driving the plurality of data lines.

The data driving unit 1020 may include at least one Source Driver Integrated Circuit (SD-IC).

Each Source Driver Integrated Circuit (SD-IC) may include a shift register, a latch circuit, a digital analog converter (DAC), an output buffer, and the like.

Further, each Source Driver Integrated Circuit (SD-IC) may further include a level shifter for shifting a voltage level of a digital image signal (DATA) corresponding to a logic signal input from the timing controller 1040 to a desired voltage level (high voltage level).

The each Source Driver Integrated Circuit (SD-IC) may be connected to a bonding pad of the display panel 1010 in a Tape Automated Bonding (TAB) scheme or Chip On Glass (COG) scheme or may be directly arranged in the display panel 1010. In some cases, the Source Driver Integrated Circuit (SD-IC) may be integrated and arranged into the display panel 1010.

The Source Driver Integrated Circuit (SD-IC) may be implemented in a Chip On Film (COF) scheme. In this event, one port of each Source Driver Integrated Circuit (SD-IC) may be bonded to at least one source printed circuit board (not shown) and the other port thereof may be bonded to the display panel 1010.

Meanwhile, the timing controller 1040 receives, together with input image data, various timing signals including a vertical synchronization signal (Vsync), a horizontal synchronization signal (Hsync), an input Data Enable (DE) signal, and a clock signal (CLK), from the outside (e.g., a host system).

The timing controller 1040 changes the input image data input from the outside to be suitable for a data signal type used in the data driving unit 1020 and then outputs the changed digital image signal (DATA). Further, in order to control the data driving unit 1020 and the gate driving unit 1030, the timing controller 1040 receives the timing signal such as the vertical synchronization signal (Vsync), the horizontal synchronization signal (Hsync), the input Data Enable (DE) signal, and the clock signal (CLK), generates various control signals, and outputs the data driving unit 1020 and the gate driving unit 1030.

For example, the timing controller 1040 outputs various Gate Control Signals (GCS) including a Gate Start Pulse (GSP), a Gate Shift Clock (GSC), and a Gate Output Enable (GOE) signal in order to control the gate driving unit 1030.

Herein, the Gate Start Pulse (GSP) controls operation start timing of the Gate Driver Integrated Circuit (GD-IC). The Gate Shift Clock (GSC) corresponds to a clock signal input to the Gate Driver Integrated Circuit (GD-IC) in common, and controls a shift timing of a scan signal (gate pulse). The Gate Output Enable (GOE) signal designates timing information of the Gate Driver Integrated Circuit (GD-IC).

Further, the timing controller 1040 outputs various Data Control Signals (DCS) including a Source Start Pulse (SSP), a Source Sampling Clock (SSC), a Source Output Enable (SOE) signal, in order to control the data driving unit 1020.

Herein, the Source Start Pulse (SSP) controls the data sampling start timing of the Source Driver Integrated Circuit (SD-IC) configuring the data driving unit 1020. The Source Sampling Clock (SSC) corresponds to a clock signal controlling sampling timing of data in each Source Driver Integrated Circuit (SD-IC). The Source Output Enable (SOE) signal controls data output timing of the Source Driver Integrated Circuit (SD-IC).

Referring to FIG. 10, the timing controller 1040 may be arranged on a source printed circuit board (not shown) in which the Source Driver Integrated Circuit (SD-IC) is bonded, and on a control printed circuit board (not shown) connected through a connection medium such as a Flexible Flat Cable (FFC) or a Flexible Printed Circuit (FPC).

In the control printed circuit board, a power controller (not shown) for supplying various voltage or current to the timing controller 1040, the display 1010, the data driving unit 1020, and the gate driving unit 1030, and controlling various voltage or current to be supplied may be further arranged.

The source printed circuit board and the control printed circuit board may be configured as one printed circuit board.

The display device 1000 according to the present embodiments may be, for example, one among a liquid crystal display device, a plasma display device, and an organic light emitting display device.

In the display device 1000, each of the plurality of subpixels (SP) arranged in the display panel 1010 has a circuit configuration in which one data line is connected to one or more gate lines.

Each subpixel may be configured as a circuit element such as a transistor, and a capacitor.

As described above, a level shifter which can be included in one kind of a driver integrated circuit of the Source Driver Integrated Circuit (SD-IC) and the Gate Driver Integrated Circuit (GD-IC) may be an advanced level shifter (ALS) according the embodiments with reference to FIGS. 3 to 9.

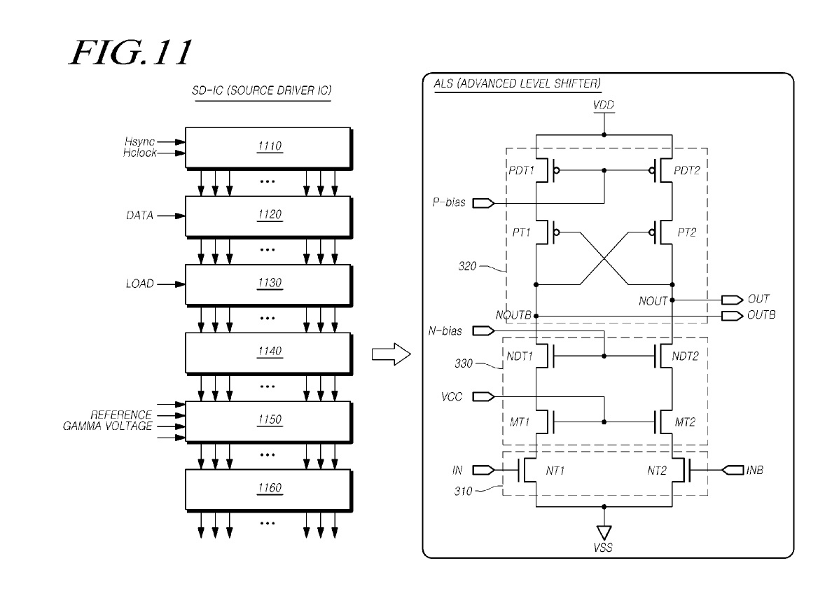

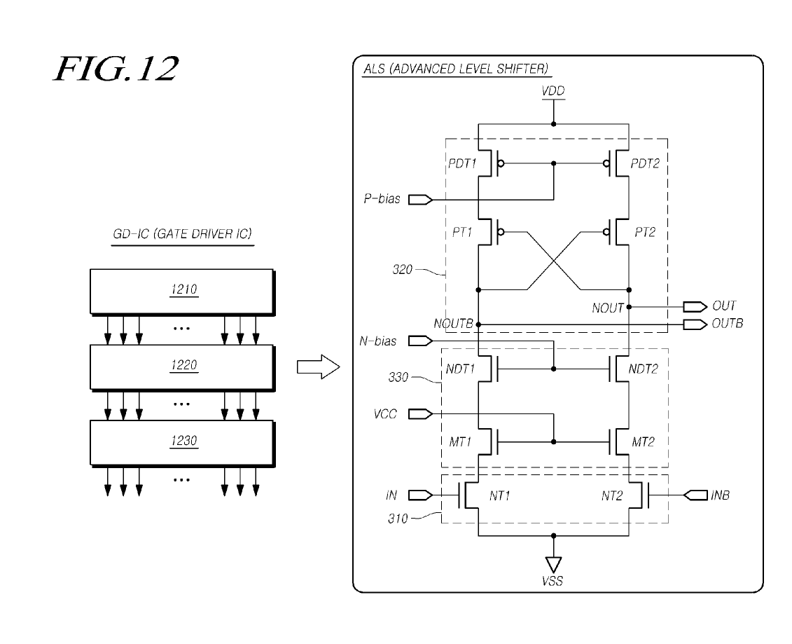

Hereinafter, the Source Driver Integrated Circuit (SD-IC) including the advanced level shifter (ALS) according to the embodiments will be briefly described with reference to FIG. 11. Further, referring to FIG. 12, the Gate Driver Integrated Circuit (GD-IC) including the advanced level shifter (ALS) according to the embodiments will be briefly described.

FIG. 11 is a block diagram of a source driver integrated circuit (SD-IC) in the display device 1000 according to the present embodiments.

Referring to FIG. 11, in the display device 1000 according to the embodiments, the source driver integrated circuit (SD-IC) includes a shift resistor 1110, a latch circuit including a first latch 1120 and a second latch 1130, a level shifter 1140, a digital analog converter 1150, and an output buffer 1160.

The shift resistor 1110 receives a horizontal clock (Hclock) and a horizontal synchronization signal (Hsync) and sequentially operates cells of the first latch 1120 according to the horizontal clock (Hclock).

The first latch 1120 synchronizes an input digital image signal (DATA) to the horizontal clock (Hclock) and then performs sampling. Therefore, the first latch 1120 may be configured by as many cells as the number of columns, and each cell may be configured by as many latches or flip-flops as the number of bits of the digital image signal (DATA).

The second latch 1130 receives and stores all digital image signals stored in the first latch 1120 by a load. In this event, the first latch 1120 starts performing sampling of a digital image signal in a next line.

The level shifter 1140 shifts a voltage level of the digital image signal transferred to the second latch 1130.

A digital analog converter 1150 converts a digital image signal having a shifted voltage level, into an analog image signal (analog voltage) using an input reference gamma voltage.

The output buffer 1160 amplifies and outputs an analog image signal converted by the digital analog converter 1150.

Referring to FIG. 11, in the source driver integrated circuit (SD-IC), the level shifter 1140 existing between the second latch 1130 and the digital analog converter 1150 may be the advanced level shifter (ALS) described with reference to FIGS. 3 to 9.

The level shifter 1140 illustrated in FIG. 11 is indicated as an example of the advanced level shifter (ALS-Type C) of FIG. 5.

The level shifter 1140 may have any structure, as long as it is the advanced level shifter (ALS) including the voltage drop circuit 330 as shown in FIGS. 3, 4, and 5.

The level shifter 1140 may include a low voltage input circuit 310 including a first N-channel transistors (NT1) which receives an input signal (IN) corresponding to a digital image signal and a second N-channel transistor (NT2) which receives an inversion input signal (INB) obtained by inverting the input signal, a high voltage output circuit 320 for receiving a driving voltage (VDD) and outputting, to first and second output ports (NOUT and NOUTB), an output signal (OUT) of a high voltage level corresponding to a voltage level of the driving voltage (VDD) and an inversion output signal (OUTB) obtained by inverting the output signal, and a voltage drop circuit 330 which is electrically connected between the drain nodes of the first and second N-channel transistors (NT1 and NT2) in the low voltage input circuit 310 and the first and second output ports (NOUT and NOUTB) in the high voltage output circuit 320, and lowers voltages of the drain nodes of the first and second N-channel transistors (NT1 and NT2) in comparison with the output signal (OUT) and the inversion output signal (OUTB). Herein, the output signal (OUT) of the high voltage level corresponds to a digital image signal having a shifted voltage level.

FIG. 12 is a block diagram of a gate driver integrated circuit (GD-IC) in the display device 1000 according to the present embodiments.

Referring to FIG. 12, in the display device 1000 according to the embodiments, the gate driver integrated circuit (GD-IC) may include a shift register 1210 for generating and outputting a logic signal for determining turning on/off of a gate line on the basis of a Gate Control Signal (GCS), a level shifter 1220 for shifting and outputting a voltage level of a logic signal output from the shift register 1210, and an output buffer 1230 for outputting a signal output from the level shifter 1220 to the gate line as a scan signal output from the level shifter 1220.

Referring to FIG. 12, the level shifter 1220 included in the gate driver integrated circuit (GD-IC) may be implemented as the advanced level shifter (ALS) described with reference to FIGS. 3 to 9.

In FIG. 12, the level shifter 1220 included in the gate driver integrated circuit (GD-IC) which corresponds to an advanced level shifter (ALS) having a structure of a type C is shown, but, as long as the gate driver integrated circuit (GD-IC) includes an advanced level shifter (ALS) having a structure of a type A or B as well as the first and second voltage drop transistors (NDT1 and NDT2), the gate driver integrated circuit (GD-IC) may be implemented by any advanced level shifter (ALS).

Referring to FIG. 12, the level shifter 1220 of the gate driver integrated circuit (GD-IC) implemented by the advanced level shifter (ALS) may include a low voltage input circuit 310 including a first N-channel transistors (NT1) which receives an input signal (IN) corresponding to a logic signal output from the shift resistor 1210 and a second N-channel transistor (NT2) which receives an inversion input signal (INB) obtained by inverting the input signal, a high voltage output circuit 320 for receiving a driving voltage (VDD) and outputting, to first and second output ports (NOUT and NOUTB), an output signal (OUT) of a high voltage level corresponding to a voltage level of the driving voltage (VDD) and an inversion output signal (OUTB) to which the output signal is inverted, and a voltage drop circuit 330 which is electrically connected between the drain nodes of the first and second N-channel transistors (NT1 and NT2) in the low voltage input circuit 310 and the first and second output ports (NOUT and NOUTB) in the high voltage output circuit 320, and lowers voltage levels of the drain nodes of the first and second N-channel transistors (NT1 and NT2) in comparison with the output signal (OUT) and the inversion output signal (OUTB).

Transistors described in the present specification may be, for example, a Metal Oxide Silicon Field Effect Transistor (MOS-FET).

According to the present embodiments as described above, an advanced level shifter (ALS) which enables a rapid voltage level conversion, and a source driver integrated circuit (SD-IC) and a gate driver integrated circuit (GD-IC) which include the same can be provided.

Further, according to the present embodiments, an advanced level shifter (ALS) which has a circuit structure allowing miniaturization and high performance, and a source driver integrated circuit (SD-IC) and a gate driver integrated circuit (GD-IC) which include the same can be provided.

Further, according to the present embodiments, an advanced level shifter (ALS) which implements transistors (NT1 and NT2) receiving an input signal as low voltage transistors, and a source driver integrated circuit (SD-IC) and a gate driver integrated circuit (GD-IC) which include the same can be provided.

Further, according to the present embodiments, an advanced level shifter (ALS) which can reduce a deviation between a rising time and a falling time of an output signal and shorten the rising time, and a source driver integrated circuit (SD-IC) and a gate driver integrated circuit (GD-IC) which include the same can be provided.

The above description and the accompanying drawings provide an example of the technical idea of the present invention for illustrative purposes only. Those having ordinary knowledge in the technical field, to which the present invention pertains, will appreciate that various modifications and changes in form, such as combination, separation, substitution, and change of a configuration, are possible without departing from the essential features of the present invention. Therefore, the embodiments disclosed in the present invention are intended to illustrate the scope of the technical idea of the present invention, and the scope of the present invention is not limited by the embodiment. The scope of the present invention shall be construed on the basis of the accompanying claims in such a manner that all of the technical ideas included within the scope equivalent to the claims belong to the present invention.

What is claimed is:

1. A level shifter comprising:
first and second N-channel transistors configured to receive an input signal of a low voltage level and an inversion input signal obtained by inverting the input signal;
first and second high voltage output transistors configured to receive a driving voltage and output, to first and second output ports, an output signal of a high voltage level corresponding to a voltage level of the driving voltage, and an inversion output signal obtained by inverting the output signal;
first and second current control transistors configured to be controlled by a bias voltage and control a current flowing to the first and second high voltage output transistors to be small; and
a voltage drop circuit configured to be electrically connected between drain nodes of the first and second N-channel transistors and the first and second output ports, and allow voltage levels of the drain nodes of the first and second N-channel transistors to be lower than voltage levels of the first and second output ports.

2. The level shifter of claim 1, wherein the first N-channel transistor includes a source node to which a base voltage is applied, a gate node to which the input signal is applied, and a drain node electrically connected to the second output port, and the second N-channel transistor includes a source node to which the base voltage is applied, a gate node to which the inversion input signal is applied, and a drain node electrically connected to the first output port.

3. The level shifter of claim 2, wherein the first high voltage output transistor includes a source node electrically connected to a driving voltage supply node to which the driving voltage is supplied, a drain node electrically connected to the second output port, and a gate node electrically connected to the first output port, and the second high voltage output transistor includes a source node electrically connected to the driving voltage supply node, a drain node electrically connected to the first output port, and a gate node electrically connected to the second output port.

4. The level shifter of claim 3, wherein the first current control transistor is connected between the driving voltage supply node and the source node of the first high voltage output transistor, and the second current control transistor is connected between the driving voltage supply node and the source node of the second high voltage output transistor.

5. A level shifter comprising:
a first N-channel transistor configured to receive an input signal of a low voltage level;
a second N-channel transistor configured to receive an inversion input signal obtained by inverting the input signal;
a first output port configured to output an output signal of a high voltage level corresponding to a voltage level of a driving voltage;
a second output port configured to output an inversion output signal obtained by inverting the output signal;
a first high voltage output transistor configured to receive the driving voltage and output the inversion output signal to the second output port;
a second high voltage output transistor configured to receive the driving voltage and output the output signal to the first output port;
a first voltage drop transistor configured to have a gate node to which a bias voltage is applied, and be electrically connected between a drain node of the first N-channel transistor and the second output port to control the first N-channel transistor to operate as a low voltage transistor;
a second voltage drop transistor configured to have a gate node to which the bias voltage is applied, and be electrically connected between a drain node of the second N-channel transistor and the first output port to control the second N-channel transistor to operate as a low voltage transistor;
a first margin control transistor configured to be electrically connected between the first voltage drop transistor and the drain node of the first N-channel transistor, and enable an additional voltage drop; and
a second margin control transistor configured to be electrically connected between the second voltage drop transistor and the drain node of the second N-channel transistor, and enable an additional voltage drop.

6. The level shifter of claim 5, wherein voltages which are applied to drain nodes or source nodes of the first voltage drop transistor and the second voltage drop transistor are higher than voltages which are applied to drain nodes or source nodes of the first margin control transistor and the second margin control transistor.

7. A source driver integrated circuit comprising:
a latch circuit configured to store a digital image signal;
a level shifter configured to shift a voltage level of the digital image signal;
a digital analog converter configured to convert a digital image signal having a shifted voltage level, into an analog image signal; and
an output buffer configured to output the analog image signal,
wherein the level shifter includes:
a low voltage input circuit including first and second N-channel transistors receiving an input signal corresponding to the digital image signal and an inversion input signal obtained by inverting the input signal;
first and second high voltage output transistors configured to receive a driving voltage and output, to first and second output ports, an output signal of a high voltage level corresponding to a voltage level of the driving voltage, and an inversion output signal obtained by inverting the output signal;
first and second current control transistors configured to be controlled by a bias voltage and control a current flowing to the first and second high voltage output transistors to be small; and
a voltage drop circuit configured to be electrically connected between drain nodes of the first and second N-channel transistors and the first and second output ports, and allow voltages of the drain nodes of the first and second N-channel transistors to be lower than the output signal or the inversion output signal.

8. The source driver integrated circuit of claim 7, wherein the voltage drop circuit includes:
a first voltage drop transistor configured to have a gate node to which a bias voltage is applied, and be electrically connected between a drain node of the first N-channel transistor and the second output port to control the first N-channel transistor to operate as a low voltage transistor; and
a second voltage drop transistor configured to have a gate node to which the bias voltage is applied, and be electrically connected between a drain node of the second N-channel transistor and the first output port to control the second N-channel transistor to operate as a low voltage transistor.

9. The source driver integrated circuit of claim 8, wherein the voltage drop circuit includes:
a first margin control transistor configured to be electrically connected between the first voltage drop transistor and the drain node of the first N-channel transistor, and enable an additional voltage drop; and
a second margin control transistor configured to be electrically connected between the second voltage drop transistor and the drain node of the second N-channel transistor, and enable an additional voltage drop.

10. The source driver integrated circuit of claim 9, wherein voltages which are applied to drain nodes or source nodes of the first voltage drop transistor and the second voltage drop transistor are higher than voltages which are applied to drain nodes or source nodes of the first margin control transistor and the second margin control transistor.

11. The source driver integrated circuit of claim 7, wherein the latch circuit includes a shift resistor, a first latch, and a second latch, the shift resistor receives a horizontal clock and a horizontal synchronization signal and sequentially operates cells of the first latch according to the horizontal clock, the first latch synchronizes the digital image signal to the horizontal clock and performs sampling, the second latch receives and stores the digital image signal stored in the first latch, and the level shifter shifts a voltage level of a digital image signal transferred to the second latch.

12. The source driver integrated circuit of claim 7, wherein the first N-channel transistor includes a source node to which a base voltage is applied, a gate node to which the input signal is applied, and a drain node electrically connected to the second output port, and the second N-channel transistor includes a source node to which the base voltage is applied, a gate node to which the inversion input signal is applied, and a drain node electrically connected to the first output port.

13. The source driver integrated circuit of claim 12, wherein the first high voltage output transistor includes a source node electrically connected to a driving voltage supply node to which the driving voltage is supplied, a drain node electrically connected to the second output port, and a gate node electrically connected to the first output port, and the second high voltage output transistor includes a source node electrically connected to the driving voltage supply node, a drain node electrically connected to the first output port, and a gate node electrically connected to the second output port.

14. The source driver integrated circuit of claim 13, wherein the first current control transistor is connected between the driving voltage supply node and the source node of the first high voltage output transistor, and the second current control transistor is connected between the driving voltage supply node and the source node of the second high voltage output transistor.
